(19) United States
(12) Patent Application Publication
(10) Pub. No.: US 2012/0007098 A1
(43) Pub. Date: Jan. 12, 2012

(54) TRANSISTOR AND METHOD FOR PRODUCING TRANSISTOR

(75) Inventor: Hiroyuki Sakurai, Kanagawa-ken (JP)

(73) Assignee: Kabushiki Kaisha Toshiba, Tokyo (JP)

(21) Appl. No.: 13/170,380

(22) Filed: Jun. 28, 2011

(30) Foreign Application Priority Data
Jul. 8, 2010 (JP) 2010-155612

(51) Int. Cl. H01L 29/20; H01L 21/20

(52) U.S. Cl. 257/76; 438/586; 257/194; 257/E29.089; 257/E21.09

(57) ABSTRACT

Certain embodiments provide a transistor including a semiconductor conductive layer, a drain electrode, a source electrode, and a gate electrode. The semiconductor device is III nitride-based semiconductor conductive layer including an active layer, formed on a surface of a substrate. The drain electrode and the source electrode have a titanium layer and an aluminum layer formed on the titanium layer and having a film thickness ratio of 12 to 15 with respect to the titanium layer, and the drain electrode and the source electrode come into ohmic contact with the semiconductor layer. The gate electrode is in Schottky junction with the semiconductor layer between the drain electrode and source electrode.

### CROSS REFERENCE TO RELATED APPLICATIONS

This application is based upon and claims the benefit of priority from the prior Japanese Patent Application No. 2010-155612 filed in Japan on Jul. 8, 2010; the entire contents of which are incorporated herein by reference.

### FIELD

Embodiments described herein relate generally to a transistor and a method for producing the transistor.

### BACKGROUND

In the past, known high-frequency devices include field effect transistors such as a compound semiconductor field effect transistor (MESFET: Metal-Semiconductor Field Effect Transistor) using a compound semiconductor substrate made of GaAs and InP and a Hetero junction field-effect transistor (HFET: Hetero junction FET). Next-generation high-speed devices such as GaN-HEMT (GaN-High Electron Mobility Transistor) made by forming gallium nitride-based (GaN) material on a silicon nitride (SiC) or a silicon substrate (Si) substrates or a sapphire (Al₂O₃) substrate have been researched and developed.

The GaN-HEMT includes a semiconductor layer including an active layer formed on any one of the above substrates and, further includes a drain electrode, a source electrode, and a gate electrode spaced apart from each other and formed on the semiconductor layer. Among them, in particular, drain and source electrodes coming into ohmic contact with a semiconductor layer are formed by laminating, e.g., Ti, Al, Au in this order.

In order to improve the performance of GaN-HEMT, it is required to sufficiently reduce the contact resistances between the semiconductor layer and the source/drain electrodes, respectively.

### BRIEF DESCRIPTION OF THE DRAWINGS

FIG. 1 is a cross sectional view illustrating a transistor according to an embodiment taken in a direction perpendicular to a substrate;

FIG. 2 is a figure illustrating a principle of calculating a contact resistance;

FIG. 3 is a graph illustrating a method for calculating a contact resistance value from a measured resistance between the metal bodies;

FIG. 4 is a top view illustrating an experimental system for measuring a resistance between metal bodies;

FIG. 5 is a graph illustrating relationship between calculated contact resistance values and film thickness ratios between Ti and Al;

FIG. 6 is a diagram illustrating process for producing the transistor according to the embodiment, and is a cross sectional view corresponding to FIG. 1 showing process for forming a semiconductor layer on a substrate;

FIG. 7 is a diagram illustrating process for producing the transistor according to the embodiment, and is a cross sectional view corresponding to FIG. 1 showing process for forming a drain electrode and a source electrode on the semiconductor layer;

FIG. 8 is a diagram illustrating process for producing the transistor according to the embodiment, and is a cross sectional view corresponding to FIG. 1 showing process for forming a drain electrode and a source electrode on the semiconductor layer;

FIG. 9 is a diagram illustrating process for producing the transistor according to the embodiment, and is a cross sectional view corresponding to FIG. 1 showing process for forming a drain electrode and a source electrode on the semiconductor layer;

FIG. 10 is a diagram illustrating process for producing the transistor according to the embodiment, and is a cross sectional view corresponding to FIG. 1 showing process for forming a gate electrode on the semiconductor layer; and

FIG. 11 is a diagram illustrating process for producing the transistor according to the embodiment, and is a cross sectional view corresponding to FIG. 1 showing process for forming a gate electrode on the semiconductor layer.

### DETAILED DESCRIPTION

A transistor according to one of the embodiments includes a semiconductor conductive layer, a drain electrode, a source electrode, and a gate electrode. The semiconductor device is III nitride-based semiconductor conductive layer including an active layer, formed on the surface of the substrate. The drain electrode and the source electrode have a titanium layer and an aluminum layer formed on the titanium layer and having a film thickness ratio of 12 to 15 with respect to the titanium layer, and the drain electrode and the source electrode come into ohmic contact with the semiconductor layer. The gate electrode is in Schottky junction with the semiconductor layer between the drain electrode and the source electrode.

A method for producing a transistor according to one of the embodiments includes the steps of laminating a titanium layer and an aluminum layer, forming a drain electrode and a source electrode, and forming a gate electrode. In the step of laminating the titanium layer and the aluminum layer, the titanium layer and the aluminum layer are respectively laminated in this order, with a film thickness ratio of the aluminum layer with respect to the titanium layer being 12 to 15, at positions away from each other on the III nitride-based semiconductor layer including the active layer, formed on the surface of the substrate. In the step of forming the drain electrode and the source electrode, the drain electrode and the source electrode coming into ohmic contact with the semiconductor layer and made of the titanium layer and the aluminum layer are formed by heating the substrate at a temperature in a range of 650 degrees Celsius or more to 700 degrees Celsius or less. In the step of forming the gate electrode, the gate electrode in Schottky junction with the semiconductor layer between the drain electrode and the source electrode is formed.

The transistor and the method for producing the transistor according to embodiments will be hereinafter explained in detail with reference to drawings.

FIG. 1 is a cross sectional view illustrating a transistor according to an embodiment taken in a direction perpendicular to a substrate explained later. As shown in FIG. 1, a semiconductor layer 12 made of III nitride-based material is formed on the surface of the substrate 11. The substrate is made of, for example, a silicon carbide (SiC). Alternatively, the substrate may be a substrate made of silicon or sapphire.

The semiconductor layer 12 is a semiconductor layer including an active layer providing carriers. For example, the semiconductor layer 12 includes an undoped GaN layer 13 and an undoped AlGaN layer 14 formed on the GaN layer 13. In this case, a two-dimensional electron gas channel appearing near the boundary between the GaN layer 13 and AlGaN layer 14 is an active layer.

The drain electrode 15 and the source electrode 16 are formed on the surface of the semiconductor layer 12. In other words, the drain electrode 15 and the source electrode 16 are formed on, e.g., the surface of the AlGaN layer 13. Each of the drain electrode 15 and the source electrode 16 is, for example, in a rectangular shape. The drain electrode 15 and the source electrode 16 are spaced apart from each other, and arranged in parallel to each other.

On the surface of the semiconductor layer 12, for example, a belt-shaped gate electrode 17 is formed between the drain electrode 15 and the source electrode 16 in parallel with the electrodes 15, 16.

Each of the drain electrode 15 and the source electrode 16 is made by laminating a plurality of metal films. The lowermost layers of the drain electrode 15 and the source electrode 16 are metal films capable of being in ohmic contact with the semiconductor layer 12. In other words, each of the drain electrode 15 and the source electrode 16 is an ohmic electrode.

The gate electrode 17 is made of metal coming into Schottky junction with the semiconductor layer 12. In other words, the gate electrode 17 is a Schottky electrode.

In particular, in the drain electrode 15 and the source electrode 16, the lowermost layer is a titanium (Ti) layer 18 as a metal film capable of coming into ohmic contact with the semiconductor layer 12. On the Ti layer 18, an aluminum (Al) layer 19 is laminated. On the Al layer 19, a metal layer 20 is formed. The metal layer 20 is made of any one of nickel (Ni), titanium (Ti), or gold (Au). However, the Al layer 19 is a barrier metal layer for suppressing reaction between the Ti layer 18 and the metal layer 20.

In the drain electrode 15 and the source electrode 16, the film thickness ratio between the Ti layer 18 and the Al layer 19 is as follows: Ti thickness:Al thickness=1:12 to 15. The contact resistance between the AlGaN layer 14 and the drain electrode 15/the source electrode having the above film thickness ratio is less than the contact resistance between the AlGaN layer 14 and the drain electrode 15/the source electrode 16 where the following equation does not hold: Ti thickness:Al thickness=1:12 to 15.

In order to reduce the contact resistance, each of the drain electrode 15 and the source electrode 16 preferably has a film thickness ratio satisfying the following equation: Ti thickness:Al thickness=1:12.5. However, as explained later, the contact resistance of the drain electrode 15/the source electrode 16 formed such that the film thickness ratio satisfies the equation Ti thickness:Al thickness=1:12 to 13 is almost the same as the contact resistance of the drain electrode 15/the source electrode 16 formed such that the film thickness ratio satisfies the equation Ti thickness Al thickness=1:12.5. Therefore, the drain electrode 15 and the source electrode 16 are more preferably formed to have the film thickness ratio between the Ti layer 18 and the Al layer 19 satisfying the following equation: Ti thickness:Al thickness=1:12 to 13.

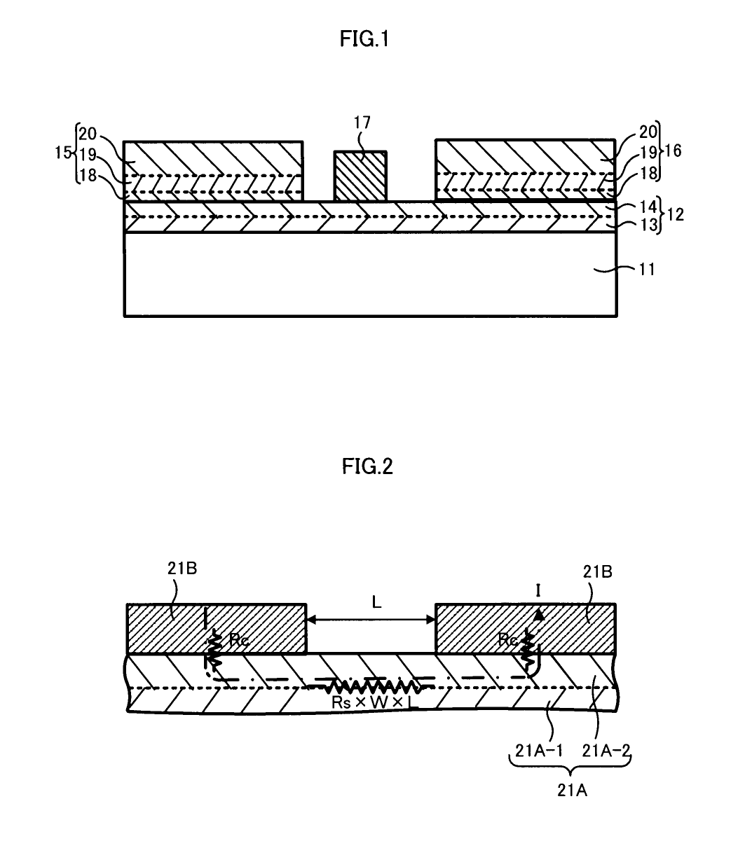

Setting the above film thickness ratio between the Ti layer 18 and the Al layer 19 in order to reduce the contact resistance between the drain electrode 15/the source electrode 16 and the semiconductor layer 12 is based on an experimental result conducted by the inventors in order to calculate the contact resistances. The experiments conducted by the inventors and the results obtained therefrom will be hereinafter explained with reference to FIGS. 2 to 5.

First, the principle of calculating a contact resistance will be explained with reference to FIG. 2. The contact resistance is a resistance at a boundary portion between the two objects in contact with each other, and the contact resistance can be determined as follows.

FIG. 2 is a figure illustrating a principle of calculating a contact resistance. As shown in FIG. 2, a contact resistance can be calculated by measuring a resistance between metal bodies 21B formed with a clearance therebetween on the surface of a semiconductor layer 21A including a GaN layer 21A-1 and a AlGaN layer 21A-2 and performing calculation on the basis of the measured resistance. More specifically, the calculation is performed as follows.

The resistance between the metal bodies 21B is measured by measuring a potential difference between the metal bodies 21B when a constant current I flows as shown by an alternate long and short dashed line in the figure. The measured resistance R(L) is expressed by the following expression (1) using a sheet resistance Rs (Ω) and a contact resistance Rc (Ω×mm²).

R(L)=(Rs×W×L)+2Rc (1)

In the above expression, W denotes a width (mm) of the semiconductor layer 21A in a direction perpendicular to this page, and L denotes a distance (mm) between the metal bodies 21B.

From the expression (1), the contact resistance Rc can be expressed as the expression (2) below.

R(0)=2Rc [symbol] Rc=R(0)/2 (2)

From the expression (2), the contact resistance Rc can be calculated by measuring R(0). However, the expression (2) is obtained by setting L to 0 in the expression (1), and the physical meaning thereof corresponds to a contact between the two metal bodies 21B. However, in a case where the metal bodies 21B are actually brought into contact with each other, and the resistance between the metal bodies 21B is measured, the measured resistance is a summation of the resistances of the metal bodies 21B and the contact resistance between the metal bodies 21B. In this case, the contact resistance between the semiconductor layer 21A and the metal bodies 21B is not measured.

Therefore, in order to know the contact resistance Rc, it is necessary to measure R(L) including the sheet resistance component (Rs×W×L) of the semiconductor layer 21A, calculate the above expression (1) from the measured resistance R(L), and transform the calculated expression (1) into the expression (2).

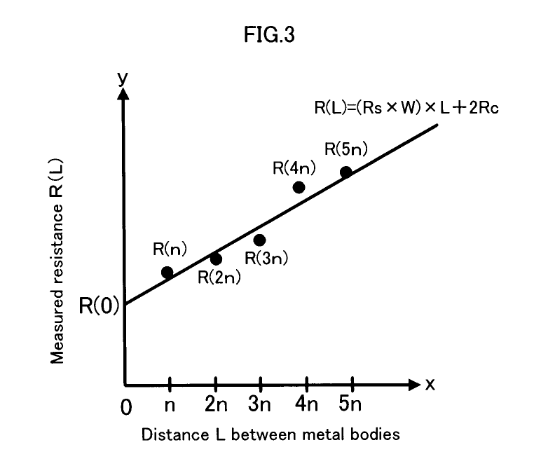

Now, the method for calculating the expression (1) will be hereinafter explained. FIG. 3 is a graph for calculating the expression (1). In the figure, the horizontal axis (x axis) denotes a distance L between the metal bodies 21B, and the vertical axis (y axis) denotes a measured resistance R(L). The expression (1) is calculated using FIG. 3. More specifically, the calculation method is as follows.

First, the distance L between the metal bodies 21B is changed, i.e., a plurality of sheet resistance components (Rs×W×L) are changed, and a plurality of resistances R(L) are measured. In this case, for example, it is assumed that the following values are respectively measured: R(L=n), R(L=2n), R(L=3n), R(L=4n), R(L=5n). In this case, it is assumed that the plurality of resistances R(L) are measured by increasing the distance L by n, i.e., by a regular increment. Alternatively, the plurality of resistances R(L) may be measured by changing the distance L irregularly.

Subsequently, the measured values R (L=n, 2n, 3n, 4n and 5n) are plotted as shown in FIG. 3. Each measured value R (L=n, 2n, 3n, 4n and 5n) is a summation of the contact resistance Rc and the sheet resistance component (Rs×W×L) of the semiconductor layer 21. However, in a case where the distance L between the metal bodies 21B is increased as described above, the contact resistance Rc does not change, and only the sheet resistance component (Rs×W×L) increases in proportional to the distance L. Therefore, each plotted dot as shown in FIG. 3 increases in proportional to the distance L.

Subsequently, an approximation straight line approximating all the plotted dots is calculated. The approximate straight line that approximates all the plotted dots may be calculated by the least squares method, for example.

The straight line approximating all the plotted dots is a straight line representing relationship between the distance L between the metal bodies 21B and the resistance R(L) between the metal bodies 21B, and corresponds to the expression (1).

In other words, the expression (1) can be obtained by measuring the plurality of resistances R(L) and calculating the approximate straight line approximating the measured result.

The contact resistance Rc can be calculated by substituting L=0 into the calculated expression (1) and transforming the expression into the expression (2).

Based on the above principle, the contact resistance between the semiconductor layer 12 and the drain electrode 15/the source electrode 16 as shown in FIG. 1 is calculated based on the data obtained by the experiment explained below. The experiment was conducted as follows.

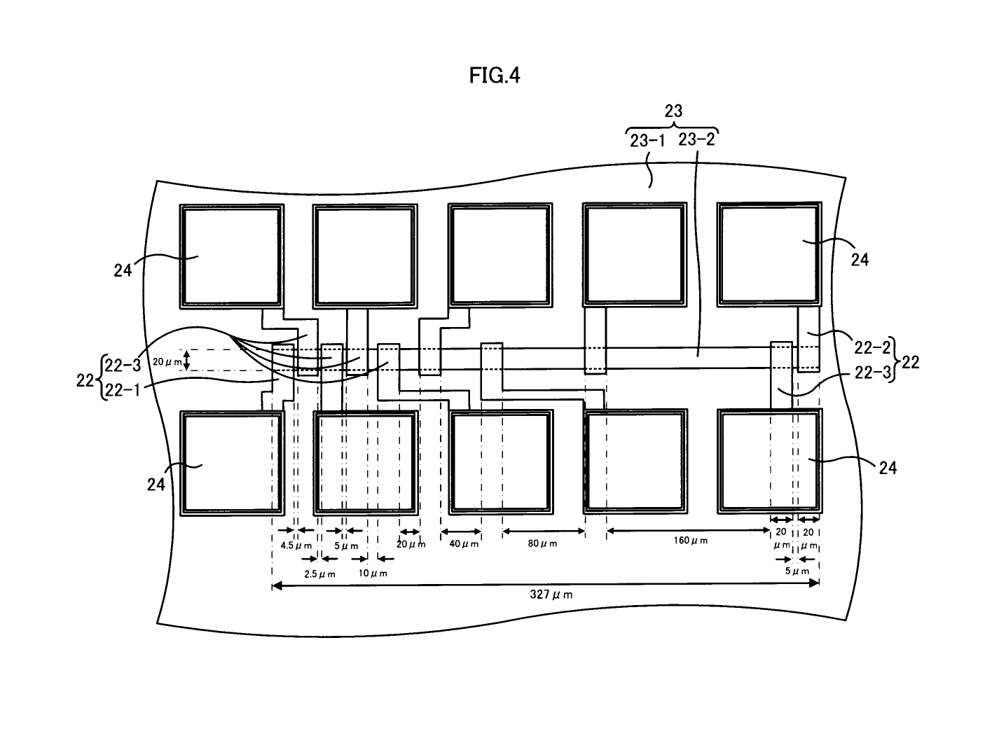

FIG. 4 is a top view illustrating an experimental system for obtaining a contact resistance between a metal body 22 and a semiconductor layer 23, wherein the metal body 22 corresponds to the drain electrode 15 or the source electrode 16 as shown in FIG. 1, and the semiconductor layer 23 corresponds to the semiconductor layer 12 as shown in FIG. 1. As shown in FIG. 4, in the experimental system, the semiconductor layer 23 corresponding to the semiconductor layer 12 as shown in FIG. 1 included a GaN layer 23-1 and an AlGaN layer 23-2. The GaN layer 23-1 has a flat shape and has a large area. The AlGaN layer 23-2 is formed in a belt shape in a portion of the surface of the layer 23-1.

AlGaN layer 23-2 was epitaxially grown on the GaN layer 23-1 to be a shape of a long belt having a length of 327 μm and a width of 20 μm.

The metal body 22 corresponding to the drain electrode 15 or the source electrode 16 as shown in FIG. 1 was formed on the surface of the GaN layer 23-1 such that the metal body 22 crossed the AlGaN layer 23-2 at a right angle and a portion of the metal body 22 overlapped the AlGaN layer 23-2. The plurality of metal bodies 22 were spaced apart with desired distances.

The plurality of metal bodies 22 were obtained by laminating Ti, Al, Au in this order, respectively. The plurality of metal bodies 22 were formed by laminating Ti, Al, Au on the surface of the GaN layer 23-1 in this order and then applying thermal treatment to the GaN layer 23-1, so that each was in ohmic contact with the AlGaN layer 23-2.

Each of the plurality of metal bodies 22 had the same width, i.e., 20 μm.

The plurality of metal bodies 22 include metal bodies 22-1, 22-2 used to pass constant currents to the semiconductor layer 23 and a plurality of metal bodies 22-3 of which resistances R(L) were measured. The metal bodies 22-1, 22-2 used to pass constant currents to the semiconductor layer 23 were arranged at both end portions of the AlGaN layer 23-2. The plurality of metal bodies 22-3 of which resistances R(L) were measured were respectively provided between the metal bodies 22-1, 22-2.

The plurality of metal bodies 22-3 to be measured were disposed with intervals of L=2.5 μm, 5 μm, 10 μm, 20 μmm, 40 μm, 80 μm and 160 μm in order from the left side of the figure. The metal bodies 22-1, 22-2 used to pass currents to the semiconductor layer 23 were disposed with intervals of 4.5 μm and 5 μm, respectively, with the metal bodies 22-3 adjacent thereto.

Each metal body 22 had a pad portion 24 integrally formed with the metal body 22.

Using the experimental system as shown in FIG. 4 explained above, a film thickness ratio of Al with respect to Ti constituting the metal body and heat processing temperature for bringing the metal body 22 to be in ohmic contact with the AlGaN layer 23-2 were respectively changed, and the resistance R(L) between the metal bodies 22-3 to be measured was measured. As the measurement method, a so-called four-terminal method was employed.

The four-terminal method is as follows. First, a constant current of about 0.1 mA passes though the active layer formed between the AlGaN layer 23-2 and the GaN layer 23-1 from the metal body 22-1 at the leftmost side of the figure to the metal body 22-2 at the rightmost side of the figure.

Subsequently, each resistance R(L) between metal bodies 22-3 adjacent to each other is measured among the plurality of metal bodies 22-3 to be measured. A probe of a measuring device for measuring the resistance R(L) is brought into contact with the pad portion 24 integrally formed with each metal body 22 so as to measure the resistance R(L).

The reason why the four-terminal method is used in the measurement is as follows. That is, in a case where the resistance between the metal bodies 22-3 to be measured is measured without employing the four-terminal method, it is measured as follows.

The probes of the measuring devices are brought into contact with the pad portions 24, and a current is passed through the metal bodies 22-3 so as to allow detection of potential difference therebetween. At this occasion, the potential difference between the metal bodies 22-3 is measured.

However, in a case where the probes of the measuring device are brought into contact with the pad portions 24, a voltage drop occurs due to this contact resistance. Therefore, the measured potential difference is different from the actual potential difference between the metal bodies 22-3. As a result, the measured resistance is different from the actual resistance between the metal bodies 22-3, and this includes the contact resistance between the probes of the measuring device and the pad portions 24.

In contrast, in a case where the four-terminal method is employed, a predetermined current is passed through the metal body 22-1 and the metal body 22-2. Therefore, in this configuration, the predetermined constant current flows between the metal bodies 22-3 to be measured even when the probes of the measuring device are not brought into contact with the metal bodies 22-3 to be measured. In this state, the probes of the measuring device are brought into contact with the metal bodies 22-3 to be measured, and the potential difference between these metal bodies 22-3 is measured. At this occasion, the predetermined constant current flows between the metal bodies 22-3 to be measured. Therefore, an extremely small current flowing through the metal bodies 22-3 to be measured is sufficient when the probes of the measuring device are brought into contact therewith. Therefore, the voltage drop that is caused by the contact resistance between the probes of the measuring device and metal bodies 22-3 is extremely small. As a result, the measured potential difference is substantially the same as the actual potential difference between the metal bodies 22-3. Therefore, the measured resistance hardly includes the contact resistance between the probe of the measuring device and the pad portion 24, and is substantially the same as the actual resistance between the metal bodies 22-3.

As described above, the four-terminal method is a method for accurately measuring a low resistance without being affected by the contact resistance and the like. Therefore, in the present experiment, the four-terminal method was employed.

Using the experimental system as shown in FIG. 4 explained above, the resistance R(L) between the metal bodies 22-3 to be measured was measured, in a case where the metal bodies 22 whose film thickness ratios of Al with respect to Ti are either 1:8, 1:10, 1:12, 1:12.5, or 1:15 are heated at a predetermined heating temperature between 550 degrees Celsius to 900 degrees Celsius. The predetermined heating temperature is either 550 degrees Celsius, 600 degrees Celsius, 650 degrees Celsius, 675 degrees Celsius, 700 degrees Celsius, 750 degrees Celsius, 800 degrees Celsius, 850 degrees Celsius, or 900 degrees Celsius.

In the present experiment, the resistance between the metal bodies 22-3 was not measured where the film thickness ratio of Al with respect to Ti is larger than 1:15. This is because, in a case where a metal body 22 whose film thickness ratio of Al with respect to Ti was larger than 1:15 is formed, the surface of the metal body 22 had unevenness to such an extent that it cannot be employed as an electrode.

FIG. 5 is a graph illustrating relationship between the contact resistances Rc calculated from the measured resistance R(L) according to the above method and film thickness ratios of Al with respect to Ti. In the figure, the horizontal axis denotes a film thickness ratio of Al with respect to Ti, and the vertical axis denotes a contact resistance Rc.

As shown in FIG. 5, as the heating temperature increased, the contact resistance Rc decreased in general. However, when the heating temperature became equal to or more than 750 degrees Celsius, the temperature of Al constituting the metal body 22 attained a temperature equal to or more than a melting point, and the metal body 22 melted and its shape changed. This means that, in the field effect transistor, drain electrode 15 and the source electrode 16 might be deformed. Therefore, it is impossible to employ the contact resistance Rc at such a high temperature.

On the contrary, when the heating temperature becomes equal to or less than 600 degrees Celsius, the contact resistance Rc became higher than those in the other cases in which the temperatures are high. Therefore, it is impossible to employ the contact resistance Rc at such a low temperature.

When the heating temperature becomes equal to or more than 750 degrees Celsius or becomes equal to or less than 600 degrees Celsius, the above problems occur. Therefore, the result of FIG. 5 is taken into consideration only in the range where the heating temperature is 650 degrees Celsius or more to 700 degrees Celsius or less.

The contact resistance of the metal body 22-3 whose film thickness ratio between Ti and Al is 1:12 to 15 was less than the contact resistance of the metal body 22-3 whose film thickness ratio between Ti and Al is 1:8 or 1:10. Further, the contact resistance of the metal body 22-3 was substantially constant in the range in which the film thickness ratio between Ti and Al is 1:12 to 15, and in particular, the smallest contact resistance of the metal body 22-3 was obtained when the film thickness ratio between Ti and Al is 1:12.5.

In the range in which the film thickness ratio between Ti and Al is 1:12 to 15, the smallest contact resistance was obtained in a case where the heating temperature is 675 degrees Celsius.

The above result of the experiment indicated that the ratio between the Ti thickness and the Al thickness constituting the drain electrode 15 and the source electrode 16 is preferably satisfies Ti thickness:Al thickness=1:12 to 15. In other words, the experiment indicated that the contact resistance can be reduced to a level less than the contact resistance with the AlGaN layer 14 by forming the drain electrode 15 and the source electrode 16 so that the following equation is satisfied: Ti thickness Al thickness=1:12 to 15.

Further, the experiment indicated that, when the ratio between the Ti thickness and the Al thickness satisfies Ti thickness:Al thickness=1:12.5, the smallest contact resistance can be obtained. However, the contact resistance is constant in the range where Ti thickness:Al thickness=1:12 to 15 is satisfied. Therefore, it is understood that, when Ti thickness:Al thickness=1:12 to 13 is satisfied, a small contact resistance can be achieved, just like the case where the ratio between the Ti thickness and the Al thickness satisfies Ti thickness Al thickness=1:12.5.

Further, in a case where the drain electrode and the source electrode 16 are formed to satisfy Ti thickness:Al thickness=1:12 to 15, the heating temperature is preferably 650 degrees Celsius or more to 700 degrees Celsius or less in order to bring the drain electrode 15 and the source electrode 16 into ohmic contact with the semiconductor layer 12, and more preferably, it is 675 degrees Celsius.

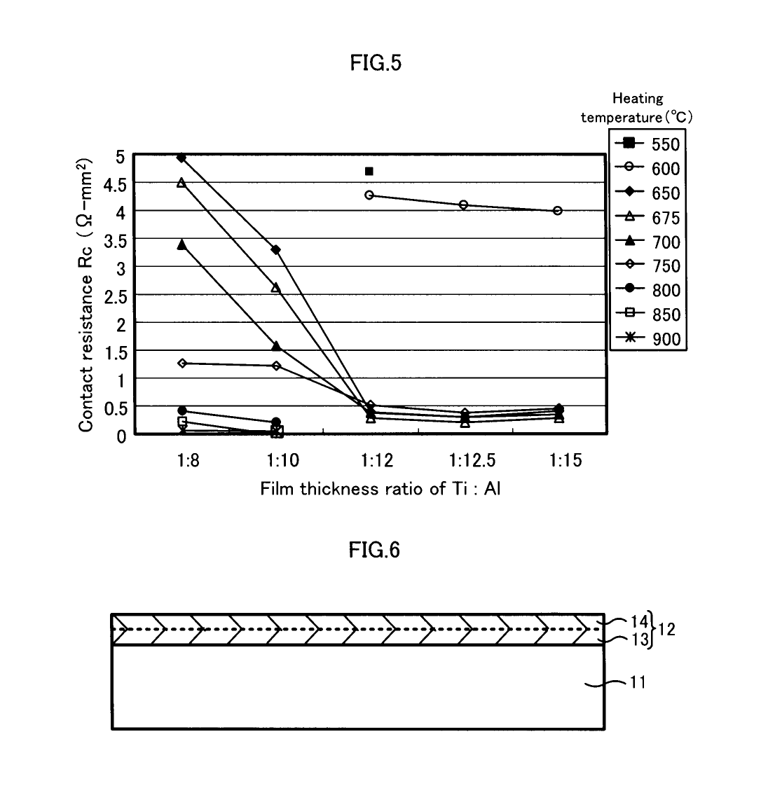

Subsequently, the method for producing the transistor will be explained with reference to FIGS. 6 to 11. FIGS. 6 to 11 are diagrams each illustrating the method for producing the transistor according to the embodiment, and are cross sectional views corresponding to FIG. 1.

First, as shown in FIG. 6, the semiconductor layer 12 made of, e.g., III nitride-based material is formed on the SiC substrate 11. More specifically, for example, the GaN layer 13 is formed on the SiC substrate 11, and the AlGaN layer 14 is formed on the GaN layer 13. The GaN layer 13 and the AlGaN layer 14 are epitaxially grown, for example.

Subsequently, the drain electrodes 15, the source electrode 16, and the gate electrode 17 are formed on the surface of the semiconductor layer 12, i.e., the AlGaN layer 14, by liftoff technique using lithography technology, for example. More specifically, they are formed as follows.

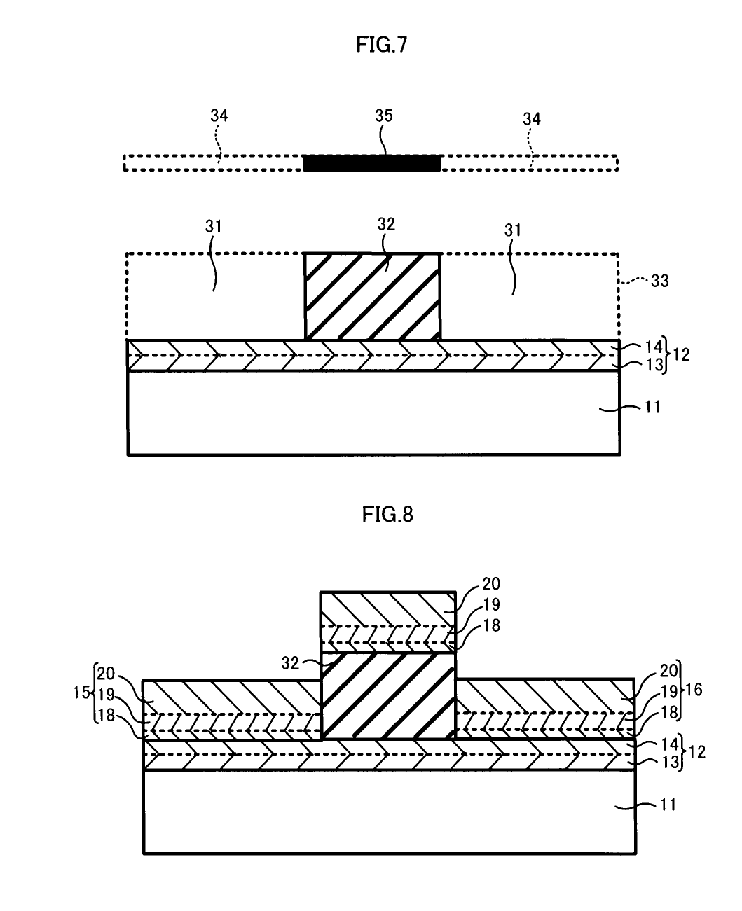

First, as shown in FIG. 7, a first photoresist layer 32 having an opening portion 31 at a predetermined portion is formed on the surface of the semiconductor layer 12, i.e., on the surface of the AlGaN layer 14.

This first photoresist layer 32 is formed as follows. First, a photoresist material 33 is uniformly applied to the AlGaN layer 14. Subsequently, using a mask 35 having opening portions 34 at predetermined portions, the applied photoresist material 33 is exposed to light. Subsequently, the exposed photoresist material 33 is developed. With the above processes, the first photoresist layer 32 is formed.

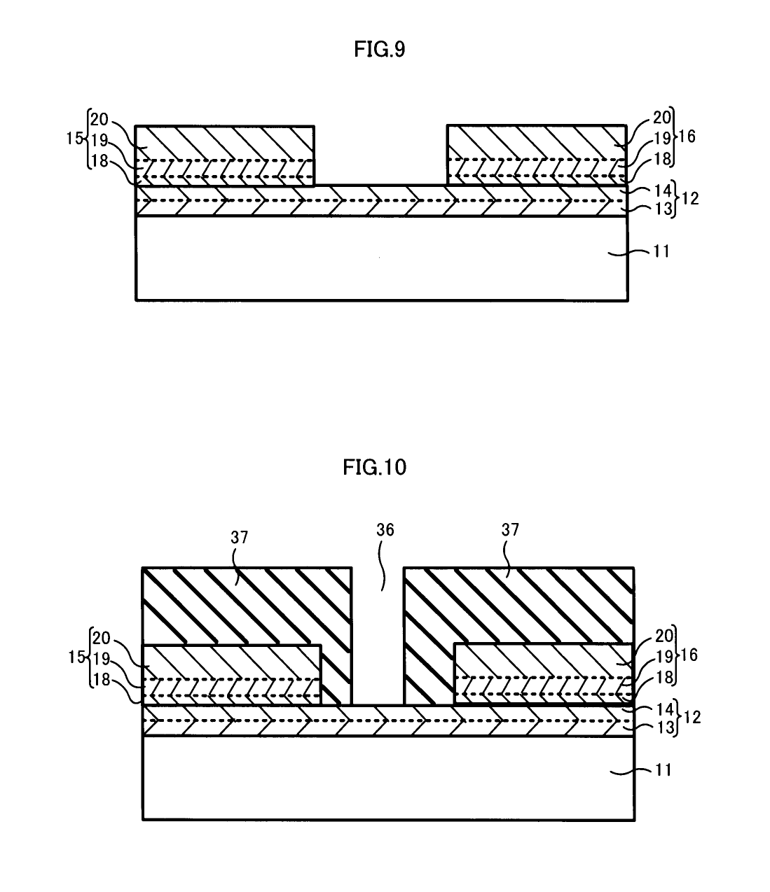

Subsequently, as shown in FIG. 8, using the first photoresist layer 32 as a mask, the Ti layer 18, the Al layer 19, and the metal layer 20 are laminated by evaporation in this order on the surface of the semiconductor layer 12 including the photoresist layer 32. The metal layer 20 is made of either nickel (Ni), titanium (Ti), or gold (Au). It should be noted that the Ti layer and the Al layer 19 are laminated so that a thickness ratio therebetween satisfies Ti:Al=1:12 to 15. Thereafter, the SiC substrate 11 is subjected to heating processing at a temperature in a range of, e.g., 650 degrees Celsius or more to 700 degrees Celsius or less, whereby the source electrode 16 and the drain electrode 15 having ohmic contact property to the semiconductor layer 12 are formed.

In this process, the film thickness ratio between the Ti layer 18 and the Al layer 19 is set so that Ti:Al=1:12.5 is satisfied. However, more preferable film thickness ratio is not limited thereto. The film thickness ratio may be set so that Ti:Al=1:12 to 13 is satisfied. On the other hand, the heating temperature of the SiC substrate 11 is preferably at 675 degrees Celsius.

Subsequently, as shown in FIG. 9, the first photoresist layer 32 is removed from the surface of the semiconductor layer 12. At this occasion, the metal films 18, 19 and 20 formed as well as the first photoresist layer 32 on the resist layer 32 are also removed.

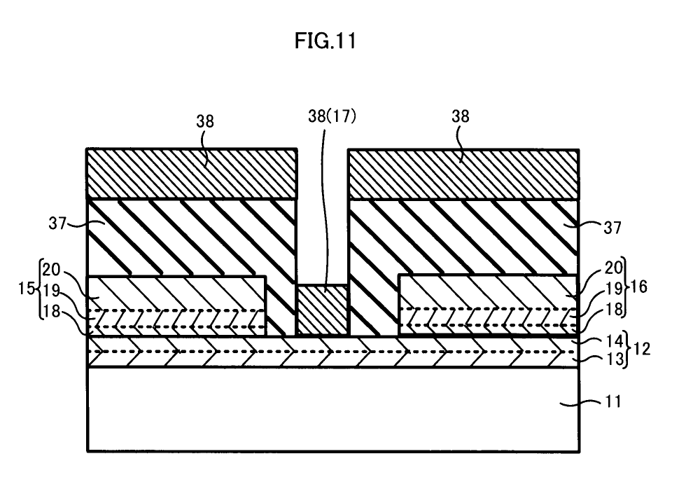

Subsequently, the gate electrode 17 is formed in the same manner as the method for forming the drain electrode 15 and the source electrode 16. More specifically, first, as shown in FIG. 10, a second photoresist layer 37 having an opening portion 36 at a predetermined portion is formed on the surface of the semiconductor layer 12, i.e., on the surface of the AlGaN layer 14. The method for forming the second photoresist layer 37 is the same as the method for forming the first photoresist layer 32.

Subsequently, as shown in FIG. 11, using the second photoresist layer 37 as a mask, a metal 38 constituting the gate electrode 17 is evaporated on the surface of the semiconductor layer 12 including the photoresist layer 37. The metal 38 used at this occasion is a metal coming into Schottky junction with the semiconductor layer 12. As described above, after the metal 38 is evaporated, the substrate 11 including the semiconductor layer 12 is subjected to heating processing, whereby the gate electrode 17 coming into Schottky junction with the semiconductor layer 12 is formed.

Finally, the second photoresist layer 37 is removed from the surface of the semiconductor layer 12. At this occasion, the metal 38 formed on the resist layer 37 with the second photoresist layer 37 is also removed.

With the above process, the transistor as shown in FIG. 1 is formed.

According to the transistor and the method for producing the transistor of the embodiment, the drain electrode 15 and the source electrode are formed such that the film thickness ratio between the Ti layer 18 and the Al layer 19 satisfies Ti:Al=1:12 to 15. Therefore, the transistor and the method for producing the transistor having a small contact resistance between the semiconductor layer 12 and the drain electrode 15/the source electrode 16 can be provided.

The transistor having a small contact resistance can be driven with a lower power consumption, and the amount of heat generation can be reduced. Therefore, operating characteristics of the transistor can be stabilized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above transistor and the method for producing the transistor according to the embodiment is an HEMT and a method for producing the HEMT using GaN as a semiconductor material. However, the same effects as those of the above transistor according to the embodiment can be obtained by applying the invention to the transistor and the method for producing the transistor according to another embodiment as long as the transistor and the method for producing the transistor uses GaN as a semiconductor material.

What is claimed is:

1. A transistor comprising:
a III nitride-based semiconductor conductive layer, including an active layer, formed on a surface of a substrate;
a drain electrode and a source electrode including a titanium layer and an aluminum layer formed on the titanium layer, wherein a film thickness ratio of the aluminum layer with respect to the titanium layer is 12 to 15, and the drain electrode and the source electrode are in ohmic contact with the semiconductor layer; and
a gate electrode coming into Schottky junction with the semiconductor layer between the electrodes.

2. The transistor according to claim 1, wherein the film thickness ratio of the aluminum layer with respect to the titanium layer is 12 to 13.

3. The transistor according to claim 2, wherein the film thickness ratio of the aluminum layer with respect to the titanium layer is 12.5.

4. The transistor according to claim 1, wherein the semiconductor layer has a structure in which a GaN layer and an AlGaN layer are laminated in this order.

5. The transistor according to claim 1, wherein each of the drain electrode and the source electrode further includes any one layer of a nickel layer, a titanium layer, and a gold layer disposed on the aluminum layer.

6. A method for producing a transistor, comprising the steps of:
respectively laminating a titanium layer and an aluminum layer, in this order, at positions spaced apart from each other on a III nitride-based semiconductor layer, including an active layer, formed on a surface of a substrate, such that a film thickness ratio of the aluminum layer with respect to the titanium layer is 12 to 15;
forming a drain electrode and a source electrode that are made of the titanium layer and the aluminum layer and come into ohmic contact with the semiconductor layer, by heating the substrate at a temperature in a range of 650 degrees Celsius or more to 700 degrees Celsius or less; and
forming a gate electrode coming into Schottky junction with the semiconductor layer between the electrodes.

7. The method for producing the transistor according to claim 6, wherein the film thickness ratio of the aluminum layer with respect to the titanium layer is 12 to 13.

8. The method for producing the transistor according to claim 7, wherein the film thickness ratio of the aluminum layer with respect to the titanium layer is 12.5.

9. The method for producing the transistor according to claim 6, wherein a heating temperature of the substrate is 675 degrees Celsius.

10. The method for producing the transistor according to claim 6, wherein the semiconductor layer is formed by laminating a GaN layer and an AlGaN layer on the surface of the substrate in this order.

11. The method for producing the transistor according to claim 6, wherein the step of laminating the titanium layer and the aluminum layer includes respectively laminating the titanium layer, the aluminum layer, and a metal layer made of any of nickel, titanium, and gold, in this order, at the positions spaced apart from each other on the semiconductor layer, and
each of the drain electrode and the source electrode includes the titanium layer, the aluminum layer, and the metal layer.
